(19) United States
(12) Patent Application Publication
(10) Pub. No.: US 2006/0118947 A1
(43) Pub. Date: Jun. 8, 2006

(54) Thermal expansion compensating flip chip ball grid array package structure

(75) Inventors: Tsorng-Dih Yuan, Hsinchu (TW); Chung-Yi Lin, Hsinchu (TW); Hsin-Yu Pan, Taipei (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/002,192

(22) Filed: Dec. 3, 2004

(51) Int. Cl. H01L 23/34

(52) U.S. Cl. 257/706

(57) ABSTRACT

A flip chip ball grid array package is provided. In one embodiment, a flip chip ball grid array package comprises an inorganic substrate, a die disposed on the substrate, the die having a coefficient of thermal expansion approximately equal to the coefficient of thermal expansion of the substrate, a heat spreader disposed over the die, the heat spreader having a coefficient of thermal expansion approximately equal to the coefficients of thermal expansion of the die and the substrate, and at least one stiffener disposed between the substrate and the heat spreader, the stiffener having a coefficient of thermal expansion approximately equal to the coefficients of thermal expansion of the die, substrate, and the heat spreader, whereby warpages in the flip chip ball grid array package are reduced.

### BACKGROUND

The present invention relates generally to flip chip ball grid array (FCBGA) packaging and, more specifically, to FCBGA packaging having reduced warpage and mechanical enhancement.

Ball grid array (BGA) is an advanced type of integrated circuit packaging technology which is characterized by the use of an organic substrate whose upper surface is mounted with a semiconductor chip and whose lower surface is mounted with a grid array of solder balls. During a surface mount technology process, for example, the BGA package can be mechanically bonded and electrically coupled to a printed circuit board (PCB) by means of these solder balls.

Flip chip ball grid array is a more advanced type of BGA technology that uses flip chip technology in mounting the active side of the chip in an upside-down manner over the substrate and bonded to the same by means of a plurality of solder bumps attached to input/output pads thereon. Due to the inherent coefficient of thermal expansion (CTE) mismatches between the FCBGA package components such as for example the chip, substrate, and underfill (an adhesive flowed between the chip and substrate), high package warpage and thermal stresses are frequently induced in the FCBGA package. These high thermal stresses and warpage not only lead to the delamination in the low-k interconnect layer(s) in the chip, but also cause solder bump cracks leading to failure, degrading the long term operating reliability of the FCBGA package. Furthermore, the substrate onto which the flip chip may be mounted can be a single layer structure, or the substrate may comprise two or many more layers of materials. Often these materials tend to be quite diverse in their composition and structure. The coefficient of thermal expansion for these different layers may be considerably different and may result in uncontrolled bending or thermal induced substrate surface distortions. Such distortions can cause failure of the flip chip or other components of the substrate.

With the introduction of new components and materials such as inorganic substrates (e.g. ceramic) for FCBGA packaging, the above problems become more pronounced due to the coefficient of thermal expansion mismatches among these components.

For these reasons and other reasons that will become apparent upon reading the following detailed description, there is a need for an improved FCBGA package that reduces and/or eliminates the component and/or board level reliability problems of conventional FCBGA packages due the coefficient of thermal expansion mismatches among these components.

### SUMMARY

The present invention is directed to integrated circuit chip packages, particularly, but not by way of limitation, to flip chip ball grid array packages. In one embodiment, a flip chip ball grid array package comprises an inorganic substrate, a die disposed on the substrate, the die having a coefficient of thermal expansion approximately equal to the coefficient of thermal expansion of the substrate, a heat spreader disposed over the die, the heat spreader having a coefficient of thermal expansion approximately equal to the coefficients of thermal expansion of the die and the substrate, and at least one stiffener disposed between the substrate and the heat spreader, the stiffener having a coefficient of thermal expansion approximately equal to the coefficients of thermal expansion of the die, substrate, and the heat spreader, whereby warpages in the flip chip ball grid array package are reduced.

### BRIEF DESCRIPTION OF THE DRAWINGS

The features, aspects, and advantages of the present invention will become more fully apparent from the following detailed description, appended claims, and accompanying drawings in which:

FIG. 1 is a cross sectional view of a semi-finished flip chip ball grid array package constructed according to aspects of the present disclosure.

FIG. 2 is a cross sectional view of the flip chip ball grid array package of FIG. 1 having a constraint plate attached to the package.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. This repetition is for the purpose of simplicity and clarity and does not in itself dictate a relationship between the various embodiments and/or configurations discussed. In addition, the formation of a first feature over or on a second feature in the description that follows may include embodiments in which the first and second features are formed in direct contact, and may also include embodiments in which additional features may be formed interposing the first and second features, such that the first and second features may not be in direct contact.

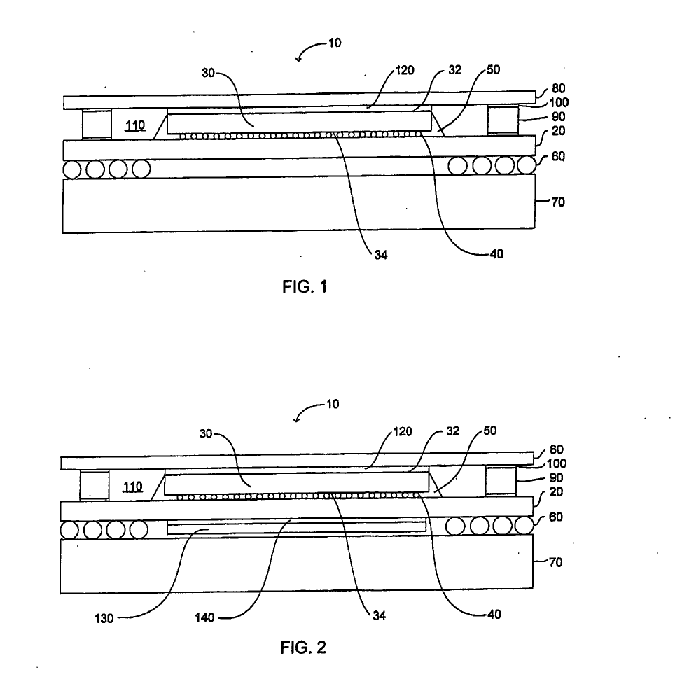

Referring to FIG. 1, illustrated is a side view diagram of a semi-finished flip chip ball grid array (FCBGA) package 10 according to one embodiment of the present invention. FCBGA package 10 includes a semiconductor device 30 such as an integrated circuit chip (hereinafter referred to as chip 30). Chip 30 has an upper surface 32 and a lower surface 34 opposite the upper surface 32. A first set of solder balls 40 (or solder bumps) is connected to contact pads (not shown) on the lower surface 34 of chip 30. The combination of the chip 30 and the solder balls 40 are commonly known as and referred to as a flip chip. Chip 30 is secured to a first substrate 20 underlying chip 30. First substrate 20 is an inorganic substrate and may include for example, a ceramic-containing substrate such as Al₂O₃. In one embodiment, the chip 30 has a coefficient of thermal expansion approximately equal to the coefficient of thermal expansion of the first substrate 20. Solder balls 40 are attached to contact pads (not shown) on the upper surface of first substrate 20. Although solder balls 40 are employed to couple chip 30 to first substrate 20, any means for coupling the chip to the substrate are within the scope of the present disclosure.

An underfill 50 may be filled between chip 30 and first substrate 20. Underfill 50 has a high tensile modulus that stiffens the FCBGA package 10 to further protect chip 30 from flexural damage. Underfill 50 may be, for example, a commercially available epoxy polymer.

A second set of solder balls 60 may be secured to contact pads (not shown) on the lower surface of first substrate 20. The combination of the first substrate 20 and the second set of solder balls 60 on the lower surface thereof are commonly known as and referred to as a ball grid array. Second set of solder balls 60 may also be secured to contact pads (not shown) on a second substrate 70, which may be a printed wire board (also sometimes called a printed circuit board) or may be a multilayer module known to those skilled in the art.

The FCBGA package 10 may also include a heat spreader 80 and one or more stiffeners 90 for preventing excess warpage of the FCBGA package 10. Heat spreader 80 is mounted on top of chip 30 and counter-balances the forces exerted by the thermal expansion mismatches between at least the chip 30 and the first substrate 20. The heat spreader 80 and the stiffeners 90 may be formed integrally or employed as discrete elements, and may substantially comprise materials having relatively high coefficients of thermal expansion. In one embodiment, the heat spreader 80 comprises copper tungsten, aluminum silicon carbide, aluminum, stainless steel, copper, nickel and/or nickel-plated copper. In one embodiment, the stiffener 90 comprises copper, copper carbon, copper tungsten, aluminum silicon carbide, aluminum, stainless steel, nickel and/or nickel-plated copper. Other materials may be implemented accordingly to meet the design requirements of a particular application and the heat spreader 80 and the stiffener 90 may comprise other materials having high coefficients of thermal expansion as is known to those skilled in the art. However, in one embodiment, heat spreader 80, stiffener 90 may have substantially equal coefficients of thermal expansion, due to substantial similarities of the materials selected for each element. In another embodiment, heat spreader 80 has a coefficient of thermal expansion approximately equal to the coefficients of thermal expansion of the chip 30 and inorganic substrate 20 whereby warpages in FCBGA package 10 are reduced. In another embodiment, a material, shape, and a thickness of heat spreader 80 may be adjusted to match the coefficient of thermal expansion of chip 30, first substrate 20, and stiffener 90. In yet another embodiment, a material, shape, and a thickness of stiffener 90 may be adjusted to match the coefficient of thermal expansion of chip 30, first substrate 20, and heat spreader 80.

Further illustrated in FIG. 1, the FCBGA package 10 may include thermal adhesive 100. The thermal adhesive may be disposed between the heat spreader 80 and the stiffeners 90, or between the first substrate 20 and the stiffeners 90, or both. The thermal adhesive 100 may comprise a viscous gel or liquid material, such as thermal grease, silver paste or solder. Thermal adhesive 100 may be applied in the form of a thin layer applied by mechanical layer spreading. Alternatively, thermal adhesive 100 may be applied by capillary action.

In one embodiment, heat spreader 80 has substantially similar dimensions as first substrate 20, although in other embodiments heat spreader 80 may be substantially smaller than first substrate 20. In either case, heat spreader 80 may be sized to substantially cover and enclose first substrate 20 in conjunction with the stiffeners 90. Accordingly, heat spreader 80 and stiffeners 90 may define a cavity 110 within which chip 30 is coupled to the first substrate 20. In one embodiment, the cavity 110 may be substantially filled with a thermo-set epoxy or other underfill material 50. In another embodiment, the underfill material 50 may only be disposed in a region proximate the chip 30 and separated from the stiffeners 90. In yet another embodiment, the underfill material 50 may be deposited around the chip 30 and between the chip 30 and the first substrate 20 before the heat spreader 80 is assembled to the stiffeners 90. In another embodiment, the underfill material 50 is deposited by injection through apertures (not shown) in the heat spreader 80 and/or the stiffeners 90 or between the stiffeners 90 and the first substrate 20.

Stiffener 90 may be disposed on first substrate 20 at a predetermined location to reduce warpage of the integrated circuit chip package thereby enhancing its structural integrity and at the same time allowing for the deposition of underfill material 50. In one embodiment, stiffener 90 is indented from about 0.5 mm to about 5 mm from one edge of first substrate 20. In a preferred embodiment, stiffener 90 is indented at about 2 mm from one edge of first substrate 20. However, those skilled in the art will understand that the indentation of stiffener 90 depends on at least the dimensions of the other components of FCBGA package 10 such as first substrate 20 and also on whether underfill material 50 may be suitably filled in cavity 110; and in general, other configurations may be implemented accordingly to meet the design criteria of a particular application.

Also shown in FIG. 1, the FCBGA package 10 may include a thermal interface material 120 disposed between the chip 30 and the heat spreader 80. Thermal interface material 120 may comprise epoxy or silver paste.

FIG. 2 shows the FCBGA package 10 of FIG. 1 having a constraint plate 130 attached onto the lower surface of first substrate 20 to protect FCBGA package 10 from flexural damage. Constraint plate 130 reduces the warpage of FCBGA package 10 caused by thermal expansion mismatches between at least the chip 30, first substrate 20, and underfill 50. Constraint plate 130 may further reduce the stress inherent in a low-k interconnect layer or layers of chip 30 including at least a passivation layer which coats on the active side of chip 30 protecting the circuits of chip 30 from the environment. By reducing the stress, delamination in the low-k interconnect layer(s) and solder bump cracks may be reduced. Constraint place 130 may comprise of one or more layers and preferably provides a sufficient degree of rigidity to first substrate 20 and to the FCBGA package 10 in general. In one embodiment, constraint plate 130 comprises a rigid metal, such as copper. In another embodiment, constraint plate 130 comprises a ceramic material. In yet another embodiment, constraint plate 80 comprises a silicon containing material. However, one skilled in the art will understand that constraint plate 130 may be of any material construction which provides the properties necessary to achieve the objectives of the present invention. Constraint plate 80 has a shape comprising of, for example a rectangle, square, circle, rhombus, ellipse, or polygon but it is understood by those skilled in the art that the shape is dependent on at least the size and shape of first substrate 20. The larger the substrate is, the larger the constraint plate 130 size must be to withstand the package warpage and/or fabrication process. Other shapes and configurations may be implemented accordingly to meet the design criteria of a particular application. Constraint plate 130 is secured to the lower surface of first substrate 20 by an adhesive 140 such as, for example epoxy. Adhesive 140 may be chosen to match or accommodate the coefficient of thermal expansion of the constraint plate 130 and first substrate 20.

The flip chip ball grid array package 10 of the present invention may have improved component and board level reliability when compared with conventional flip chip packages. The present invention may improve component and board level reliability of flip chip packages with inorganic substrates such as ceramic-containing substrates.

In the preceding detailed description, the present invention is described with reference to specifically exemplary embodiments thereof. It will, however, be evident that various modifications, structures, processes, and changes may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

What is claimed is:

1. An integrated circuit chip package comprising:
an inorganic substrate;
a die disposed on the inorganic substrate, the die having a coefficient of thermal expansion approximately equal to the coefficient of thermal expansion of the inorganic substrate; and
a heat spreader disposed over the die, the heat spreader having a coefficient of thermal expansion approximately equal to the coefficients of thermal expansion of the die and the inorganic substrate whereby warpages in the integrated circuit chip package are reduced.

2. The integrated circuit chip package of claim 1, further comprising at least one stiffener disposed between the inorganic substrate and the heat spreader, the stiffener having a coefficient of thermal expansion approximately equal to the coefficients of thermal expansion of the die, inorganic substrate, and the heat spreader.

3. The integrated circuit chip package of claim 1, wherein the stiffener comprises copper, copper carbon, copper tungsten, or aluminum silicon carbide.

4. The integrated circuit chip package of claim 1, wherein the stiffener is disposed on the inorganic substrate at a predetermined location.

5. The integrated circuit chip package of claim 2, wherein a material, shape, and a thickness of the stiffener may be adjusted to match the coefficient of thermal expansion of the die, inorganic substrate, and heat spreader.

6. The integrated circuit chip package of claim 1, wherein the inorganic substrate comprises a ceramic-containing substrate.

7. The integrated circuit chip package of claim 1, wherein the heat spreader comprises copper tungsten or aluminum silicon carbide.

8. The integrated circuit chip package of claim 1, wherein a material, shape, and a thickness of the heat spreader may be adjusted to match the coefficient of thermal expansion of the die and/or inorganic substrate.

9. The integrated circuit chip package of claim 1, further comprising a thermal interface material disposed between the die and the heat spreader.

10. The integrated circuit chip package of claim 9, wherein the thermal interface material comprises epoxy or silver paste.

11. The integrated circuit chip package of claim 1, further comprising underfill between the die and the inorganic substrate.

12. The integrated circuit chip package of claim 1, further comprising a constraint plate secured to the lower surface of the inorganic substrate so that the constraint plate has a degree of rigidity to reduce warpage due to thermal expansion mismatches between at least the die and the inorganic substrate.

13. A flip chip ball grid array (FCBGA) package comprising:
an inorganic substrate;
a die disposed on the inorganic substrate, the die having a coefficient of thermal expansion approximately equal to the coefficient of thermal expansion of the inorganic substrate; and
a heat spreader disposed over the die, the heat spreader having a coefficient of thermal expansion approximately equal to the coefficients of thermal expansion of the die and the inorganic substrate whereby warpages in the integrated circuit chip package are reduced.

14. The integrated circuit chip package of claim 13, further comprising at least one stiffener disposed between the inorganic substrate and the heat spreader, the stiffener having a coefficient of thermal expansion approximately equal to the coefficients of thermal expansion of the die, inorganic substrate, and the heat spreader.

15. The integrated circuit chip package of claim 13, wherein the stiffener comprises copper, copper carbon, copper tungsten, or aluminum silicon carbide.

16. The integrated circuit chip package of claim 13, wherein the stiffener is disposed on the inorganic substrate at a predetermined location.

17. The integrated circuit chip package of claim 14, wherein a material, shape, and a thickness of the stiffener may be adjusted to match the coefficient of thermal expansion of the die, inorganic substrate, and heat spreader.

18. The integrated circuit chip package of claim 13, wherein the inorganic substrate comprises a ceramic-containing substrate.

19. The integrated circuit chip package of claim 13, wherein the heat spreader comprises copper tungsten or aluminum silicon carbide.

20. The integrated circuit chip package of claim 13, wherein a material, shape, and a thickness of the heat spreader may be adjusted to match the coefficient of thermal expansion of the die and/or inorganic substrate.
